(19) United States
(12) Patent Application Publication
(10) Pub. No.: US 2009/0225893 A1
(43) Pub. Date: Sep. 10, 2009

(54) METHOD AND APPARATUS FOR DICTIONARY CONSTRUCTION FOR VSB CHANNEL MODELING

(75) Inventors: LIN YANG, FREMONT, CA (US); QIN LIU, FREMONT, CA (US)

Correspondence Address: FRANK F. TIAN, 331-4A THIRD AVENUE, LONG BEACH, NJ, 07740, US

(73) Assignee: LEGEND SILICON CORP., FREMONT, CA (US)

(21) Appl. No.: 12/043,158

(22) Filed: Mar. 6, 2008

(51) Int. Cl. H04L 27/02; H03D 1/24

(52) U.S. Cl. 375/270; 375/321

(57) ABSTRACT

A method for creating a dictionary for channel modeling is provided. The method comprising the steps of: providing a channel subject to modeling associated with a VSB system; over-sampling a predetermined segment; and using at least part of the over-sampled values as elements or words of the dictionary.

### CROSS-REFERENCE TO OTHER APPLICATIONS

The following applications of common assignee and filed on the same day herewith are related to the present application, and are herein incorporated by reference in their entireties:

U.S. patent application Ser. No. ______ with attorney docket number LSFFT-091.

U.S. patent application Ser. No. ______ with attorney docket number LSFFT-092.

### FIELD OF THE INVENTION

The present invention relates generally to channel modeling in a vestigial sideband (VSB) system, more specifically the present invention relates to dictionary construction for a VSB channel modeling.

### BACKGROUND

Channel modeling is one of the most important issues in a VSB communication system. It is usually done by comparing the received signal and the known transmitted signal. Typically, a known method of channel modeling is done. However, the known or initial channel modeling may not satisfy specified requirement due to estimation error caused by interference/noise and the like.

In a VSB system, a transmitter transmits signals through some media such as a radio frequency channel. Due to the geographic structure between the transmitter and the receiver, signals arriving at the receiver end, such as a mobile receiver, usually undergo a frequency selecting or fading process, which gives different frequency responseat different frequencies. In order to recover the transmitted VSB signals, e.g. using frequency domain equalizers, channel frequency response needs to be estimated

Therefore, there is a need for an improved or more accurate channel modeling based upon the initial channel modeling.

### SUMMARY OF THE INVENTION

The present invention models the channel time-domain response by a new set of basis functions. The basis functions depends on the SRRC filter frequency response and the over-sampling in time domain. In such a way, channel modeling refinement may be possible by finding the best combinations of the basis.

This invention models the channel time-domain response by elements from a redundant dictionary so that channel modeling refinement may be possible by finding the best combinations of the selected elements.

The redundant dictionary is created by having a square root raised cosine (SRRC) filter acting in Frequency domain, over-sampling in a predetermined segment in the time domain, and creating a correlation functions between elements or words of the dictionary.

A method for creating a dictionary for channel modeling is provided. The method comprising the steps of: providing a channel subject to modeling associated with a VSB system; over-sampling a predetermined segment; and using at least part of the over-sampled values as elements or words of the dictionary. A suitable receiver incorporating the method is provided therefore.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an equation representing a relationship associated with a dictionary in accordance with some embodiments of the invention.

FIG. 2 shows the spectrum of VSB signal.

FIG. 2A is frequency shifted version of VSB signal of FIG. 2.

FIG. 3 is an example raised cosine (RC, two SRRC results in a RC) based g(t) presentation in accordance with some embodiments of the invention.

FIG. 3A is an example of gₖ(.) without symbol delay and basis gₖ, gₖ(n−mᵢ) shows a shifted basis version of gₖ in accordance with some embodiments of the invention.

FIG. 3B is an example of g(.) with symbol delay mᵢ and basis gₖ, gₖ(n−mᵢ) shows a shifted basis version of gₖ in accordance with some embodiments of the invention.

FIG. 4 is a VSB receiver in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to dictionary construction for a VSB channel modeling. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of dictionary construction for a VSB channel modeling described herein. The non-processor circuits may include, but are not limited to, a radio receiver, a radio transmitter, signal drivers, clock circuits, power source circuits, and user input devices. As such, these functions may be interpreted as steps of a method to perform dictionary construction for a VSB channel modeling Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

8-VSB (8-level vestigial sideband) is a standard radio frequency (RF) modulation format chosen by the Advanced Television Systems Committee (ATSC) for the transmission of digital television (DTV) in such countries as the United States and other adopting countries. 8-VSB is used in the transmission of video data. There is also a 16-VSB mode that has 16 amplitude levels. 8-VSB is considered effective in multi-casting in that simultaneous transmission of more than one DTV program is achieved. Further, 8-VSB is also considered effective in datacasting in that the transmission of data along with a television program is achieved.

In addition, VSB transmission system possesses large bandwidth, which is needed to transmit HDTV (high definition television) programming. VSB has single side band thereby having improved or better adaptability in protecting against adjacent channel interference. Further, single side band has better performance at higher bit rates. VSB uses the entire bandwidth as a single frequency having all component parts multiplexed together. The benefits therefrom include lower broadcast power and the possibility of extended station coverage. VSB further minimizes interference with anal NTSC signals, which are required to be transmitted simultaneously with the digital signals. NTSC uses an improve the signal strength throught an entire service area, thereby allowing even remote and heavily walled locations to receive the desired signal.

It is noticed that performance depends heavily on the accuracy of channel modeling. Typical estimation proposals such as singular-value decomposition (SVD) has been proposed (see O. Edfors etc, IEEE trans comm, July 1998), and subspace tracking for channel modeling/refinement are known. These methods in general try to represent signal by combinations of several important vectors such as eigenvectors. Considering the linear transform of inverse Fourier transform, the response then consists of superimposition of multiple delays. As long as one can model the delay, strength, and phase; the channel is represented and Fourier Transform can be conducted to obtain the required frequency response of the channel.

The present invention models the channel time-domain response by a new set of basis functions. The basis functions depends on the SRRC filter frequency response and the over-sampling in time domain. In such a way, channel modeling refinement is made possible by finding the best combinations of a set of basis. It is presumed that the combined filter response of transmitting square root raised cosine (SRRC) filter, RF/IF related filter, receiving SRRC filter in a VSB system is represented as g(t). It is further presumed that the physical channel consists of N paths each with coefficient Aᵢ and delay τᵢ(i=0, . . . , N−1), with the final combined channel represented as:

$$h ( t ) = {\sum }_{i = 0}^{N - 1} {A}_{i} g ( t - {τ}_{i} ) \qquad ( Equ . 1 )$$

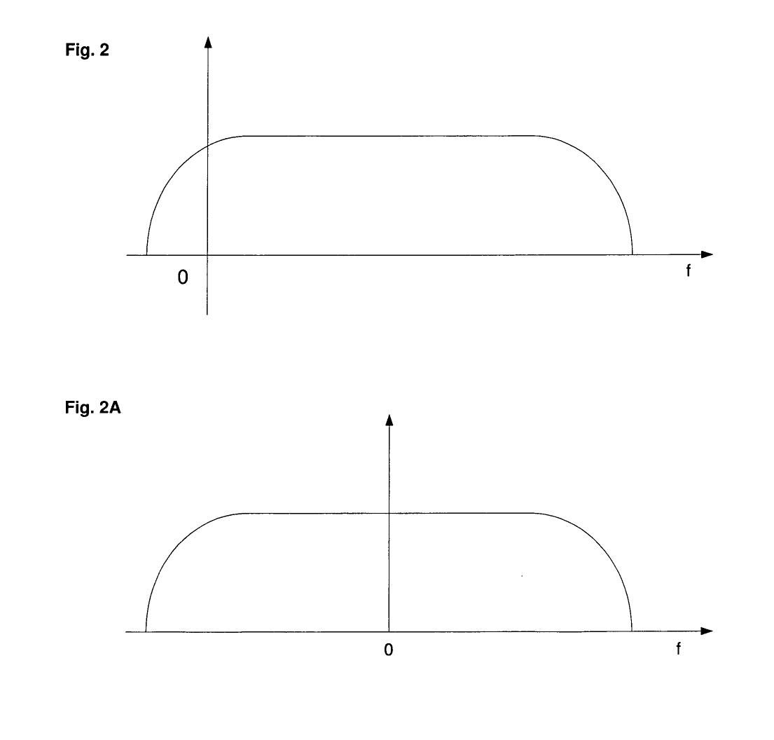

Channel modeling is to find Aᵢ and τᵢ together with g(t). Note that due to the property of the 8-vsb signal, channel defined here shall be up-shifted a frequency to correspond to the 8-vsb signals. Refer to FIGS. 2 and 2A.

Since g(t) is known to the designer if only two main SRRC filters are considered (e.g. roll-off is 0.11in a VSB system) or if measured on initial system set-up, g(t) is sampled at symbol rate (10.76 MSPS) with over-sampling rate (e.g. 1/64 or 1/128 symbol for better resolution/match) to give the initial basis, e.g. gₖ(k=0, . . . , 63) for one of the 64 phases. It is appreciated that other sampling rates are considered by the present invention. The sampling rate may be 2ⁿ with n being a finite positive integer. Alternatively any positive integer within the range would be sufficient.

It is important to have a high over-sampling basis in order to model the channel more accurately. Further, the over-sampling actions are performed in the time domain. For example, the covariance of a gₖ (k=0, . . . , 63) consists of the following entries:

gᵢ(n−δ)gⱼ(n) (Equ. 2)

Where δ means delays: −D+1, . . . , 0, . . . , D−1 respectively. D is the non-zero width of gₖ. For a fixed i, j, the above shows covariance with changing delays. As can be seen, the correlation function gᵢ(n−δ)gⱼ(n) aids in the formation of different elements or works of the dictionary in our invention. In other words, gᵢ(n−δ)gⱼ(n) or equation 2 represent a set of correlation functions.

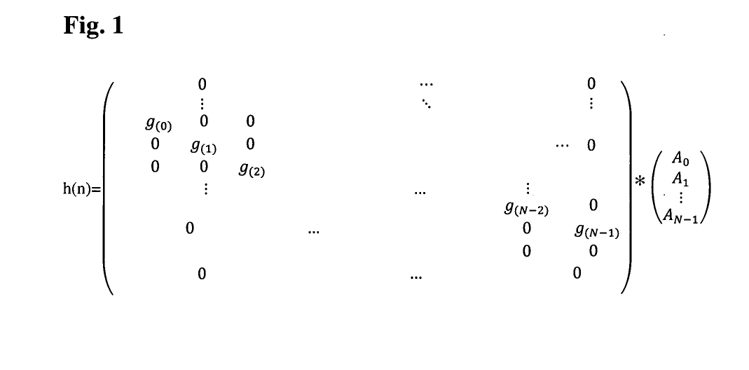

The final sampled channel h(n)=h(t) is then modeled as the N shifted (due to delay) version of these initial basis. The equation as shown in FIG. 1 that shows this model. G is a M×N matrix having M rows and N columns. A is a vector with N elements. It is noted that G is a sparse basis matrix. Finally, the dictionary is gₖ with all possible k (or 0, 1, . . . , k−1) and shifting shown below (only g0, g1, and gk−1 are shown):

For g₀(.):
g₀(.) 0 0 . . . 0
0 gₒ(.) 0 0 . . . 0
0 0 g₀(.) 0 0 . . . 0
0 0 0 . . . g₀(.)
   For g₁(.):
g₁(.) 0 0 . . . 0
0 g₁(.) 0 0 . . . 0
0 0 g₁(.) 0 0 . . . 0
0 0 0 . . . g₁(.)
   For gₖ₋(.):
gₖ₋₁(.) 0 0 . . . 0
0 gₖ₋₁(.) 0 0 . . . 0
0 0 gₖ₋₁(.) 0 0 . . . 0
0 0 0 . . . g₋₁(.)

FIG. 2 shows the spectrum of VSB signal. FIG. 2A is frequency shifted version of VSB signal. This represents a baseband RC filter. It is pulse shaped by a RC filter.

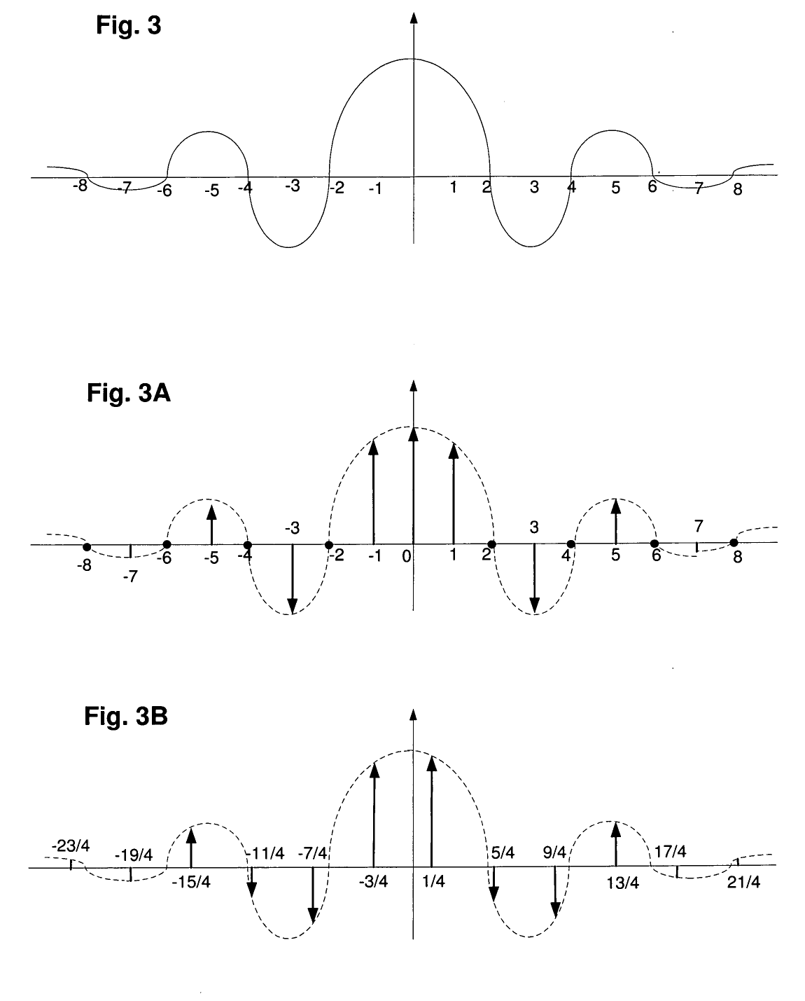

In FIG. 3 is an example of raised cosine (RC) graph representing a characteristic of a channel based g(t). Note that two Square Root Raised Cosine (SRRC) results in a RC. Note that the SRRC filter performs filtering in Frequency domain respectively. g(t) is defined as follows. It is presumed that the combined filter response of the transmitting square root raised cosine (SRRC) filter, the RF/IF related filter, and the receiving SRRC filter in a VSB system is represented as g(t). It is noted that G is a sparse basis matrix in the time domain. Likewise, the above discussions also apply to frequency representation of the channel representation by taking the Fourior transform. This way, time-shifted scheme will be replaced with frequency-rotated scheme, and G is not a sparse matrix.

FIG. 3A is an example of g(.) without symbol delay and sampling phase (I. E. phase=0. The sampling rate is associated Nyquist rate. With 0 as the central reference point, at the points −8, −7, −6, −5, −4, −3, −2, −1, 0, 1, 2, 3, 4, 5, 6, 7, 8, etc. Note that RC curves tend to decrease in amplitude rapidly. Therefore, the sampling points may be a limited, finite number. More generally, an example of g(.) with symbol delay mᵢ and basis gₖ with sampling phase is greater than 0. gₖ (n−mᵢ) shows a shifted basis version of gₖ. The sampling points are mᵢ−4, mᵢ−3, mᵢ−2, mᵢ−1, mᵢ, mᵢ+1, mᵢ+2, mᵢ+3, mᵢ+4, etc. Note in this case Mi=0.

FIG. 3B shows a different basis, it is a shift of a quarter (¼) of FIG. 1A. Points −8, −7, −6, −5, −4, −3, −2, −1, 0, 1, 2, 3, 4, 5, 6, 7, 8, of FIG. 3A now corresponds to points ¼−8, ¼−7, ¼−6, ¼−5, ¼−4, ¼−3, ¼−2, ¼−1, 0+¼, 1+¼, 2+¼, 3+¼, 4+¼, 5+¼, 6+¼, 7+¼, 8+¼, respectively.

Channel time-domain response is represented by a new set of basis functions as shown FIG. 1. As can be seen, h(n) is represent by a M×N matrix and a vector having N elements. M is greater than N, M being the number of rows and N being the number of columns. Therefore channel modeling refinement is possible by finding the best combinations of the basis.

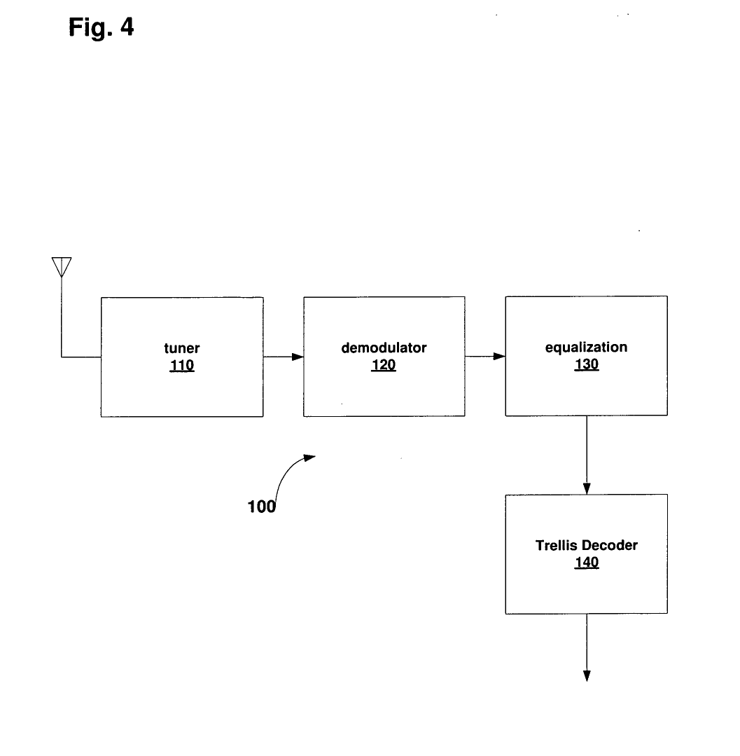

FIG. 4 is a block diagram of a conventional digital television receiver 100, which can process a VSB signal, is shown. The digital television receiver 100 includes a tuner 110, a demodulator 120, an equalizer 130, and a TCM (Trellis-coded Modulation) decoder 140. TCM coding may use an error correction technique, which may improve system robustness against thermal noise. TCM decoding may have more robust performance ability and/or a simpler decoding algorithm. The output signal OUT of the TCM decoder 140 may be processed by a signal processor and output as multimedia signals (e.g., display signals and/or audio signals).

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. A method for creating a dictionary for channel modeling, comprising the steps of:
providing a channel subject to modeling associated within a VSB system; over-sampling a predetermined segment; and
using at least part of the over-sampled values as elements or words of the dictionary.

2. The method of claim 1, wherein the over-sampling step is performed in the time domain.

3. The method of claim 8, wherein the over-sampling step comprises a rate for dividing the predetermined segment by about ½⁵ to ½⁸.

4. The method of claim 1, further comprising the step of providing a SRRC filter associated with a channel subject to modeling.

5. The method of claim 4, wherein the SRRC filter acts in the Frequency domain.

6. The method of claim 4 further comprising the step of providing the correlation functions associated with the fixed SRRC to provide more elements or words for the dictionary.

7. A VSB receiver comprising:
a channel estimator having a method for creating a dictionary for channel modeling; the method comprising the steps of:
providing a channel subject to modeling associated with a VSB system; over-sampling a predetermined segment; and
using at least part of the over-sampled values as elements or words of the dictionary.

8. The receiver of claim 7, wherein the over-sampling step is performed in the time domain.

9. The receiver of claim 8, wherein the over-sampling step comprises a rate for dividing the predetermined segment by about ½⁵ to ½⁸.

10. The receiver of claim 7, further comprising the step of providing a SRRC filter associated with a channel subject to modeling.

11. The receiver of claim 10, wherein the SRRC filter acts in the Frequency domain.

12. The receiver of claim 10 further comprising the step of providing the correlation functions associated with the fixed SRRC to provide more elements or words for the dictionary.
